(19) United States
(12) Patent Application Publication
(10) Pub. No.: US 2020/0064694 A1
(43) Pub. Date: Feb. 27, 2020

(54) LIGHT EMITTING DIODE, BACKLIGHT DEVICE AND DISPLAY DEVICE

(71) Applicant: XIAMEN TIANMA MICRO-ELECTRONICS CO., LTD., Xiamen (CN)

(72) Inventor: ZhongYuan Lin, Xiamen (CN)

(21) Appl. No.: 16/672,522

(22) Filed: Nov. 4, 2019

(30) Foreign Application Priority Data
Apr. 30, 2019 (CN) 201910361603.7

(51) Int. Cl. G02F 1/1335; F21V 8/00; H01L 33/62; H01L 33/50; H01L 33/48

(52) U.S. Cl. CPC G02F 1/133608; G02F 1/133603; G02B 6/009; G02B 6/0073; H01L 33/62; H01L 33/507; H01L 33/486; G02B 6/0068

(57) ABSTRACT

The disclosure provides a light emitting diode, a backlight device and a display device. The light emitting diode includes a bracket and a light emitting diode chip. The bracket includes two first side plates arranged opposite to each other, two second side plates arranged opposite to each other, and a base plate, where at least one of the two first side plates is a light-transmitting side plate. The light emitting diode chip is arranged in a receptacle, where the receptacle is formed by the two first side plates arranged opposite to each other, the two second side plates arranged opposite to each other, and the base plate.

### CROSS REFERENCES

This application claims priority to Chinese Patent Application No. 201910361603.7, filed on Apr. 30, 2019, which is hereby incorporated by reference in its entirety.

### FIELD

The application relates to the field of display technologies and particularly to a light emitting diode, a backlight device and a display device.

### BACKGROUND

The liquid crystal display device is a kind of flat panel display. The operating principle of the liquid crystal display device is to utilize a modulating action of liquid crystal materials on a light under an electric field to produce a variety of light and shade changes so as to form an image. Since the liquid crystal materials are nonluminous by themselves, the liquid crystal display device needs a specialized backlight device.

The backlight device is one of critical parts of the liquid crystal display device. The main function of the backlight device is to provide a liquid crystal panel with a uniform and high-brightness backlight. The basic principle of the backlight device is to convert the commonly-used point or linear illuminator into the high-brightness and uniform-gray face illuminator via the effective optical mechanism, to thereby enable the liquid crystal panel to display the image normally.

According to a distribution position of a light source, the backlight device may be classified into two types: a straight-down backlight device and a side-entry backlight device. Since the side-entry backlight device meets the thin-type requirement of the current display device and may provide the high-brightness and uniform plane light source, a majority of liquid crystal display devices employ the side-entry backlight device.

### SUMMARY

Embodiments of the disclosure provide a light emitting diode, a backlight device and a display device.

Embodiments of the disclosure provide a light emitting diode. The light emitting diode includes a bracket and a light emitting diode chip. The bracket includes two first side plates arranged opposite to each other, two second side plates arranged opposite to each other, and a base plate, where at least one of the two first side plates is a light-transmitting side plate. The light emitting diode chip is arranged in a receptacle, where the receptacle is formed by the two first side plates arranged opposite to each other, the two second side plates arranged opposite to each other, and the base plate.

In some embodiments, the disclosure further provides a backlight device, which includes at least one optical membrane and a light source which includes a plurality of light emitting diodes, where at least one light emitting diode is a first light emitting diode which is the light emitting diode according to any one of the embodiments described above.

The disclosure further provides a display device which contains the backlight device in any one of the embodiments of the present application. The display device includes the backlight device, a lower polarizer, a display panel, an upper polarizer and a cover plate superposed in sequence. The display panel further includes an array substrate and a color film substrate in paired box with the array substrate. There is a liquid crystal layer between the array substrate and the color film substrate.

In the technical solution of the disclosure, in the bracket of the light emitting diodes, at least one first side plate is the light-transmitting side plate from which the lights may exit, to thereby increase the light-emitting angle of the light emitting diodes. When the light emitting diodes are installed on the backlight device, the shadow of the backlight device may be reduced and the light-emitting uniformity of the corresponding backlight device may be increased. The probability that the backlight device produces the shadow is lower, so that the display effect of the display device using this backlight device is better.

### BRIEF DESCRIPTION OF THE DRAWINGS

In order to describe the embodiments of the present disclosure more clearly, the drawings illustrated in the embodiments of the present disclosure will be briefly described below.

FIG. 1 is a structural schematic diagram of a partial section of the backlight device according to some embodiments in the related art.

FIG. 2 is a schematic diagram of a brightness of a light emitting diode according to some embodiments in the related art.

FIG. 3 is a schematic diagram of the cross-section structure of a light emitting diode according to some embodiments of the disclosure.

FIG. 4 is a top view of a light emitting diode according to another embodiment of the disclosure.

FIG. 5 is a top view of a light emitting diode according to another embodiment of the disclosure.

FIG. 6 is a top view of a light emitting diode according to another embodiment of the disclosure.

FIG. 7 is a top view of a light emitting diode according to another embodiment of the disclosure.

FIG. 8 is a contrast diagram of the light-emitting angles of the light emitting diode before and after the improvement.

FIG. 9 is a schematic diagram of the partial structure of a display device according to some embodiments of the disclosure.

FIG. 10 is a structural schematic diagram of a display device according to another embodiment of the disclosure.

FIG. 11 is a structural schematic diagram of a display device according to another embodiment of the disclosure.

FIG. 12 is a contrast diagram of the states of installing the light emitting diode to the light bar before and after the improvement.

FIG. 13 is a structural schematic diagram of a display device according to another embodiment of the disclosure.

FIG. 14 is a structural schematic diagram of a display device according to another embodiment of the disclosure.

FIG. 15 is a structural schematic diagram of a display device according to another embodiment of the disclosure.

FIG. 16 is a structural schematic diagram of a display device according to another embodiment of the disclosure.

FIG. 17 is a structural schematic diagram of a display device according to another embodiment of the disclosure.

FIG. 18 is a structural schematic diagram of a display device according to another embodiment of the disclosure.

FIG. 19 is a structural schematic diagram of a mobile terminal according to another embodiment of the disclosure.

Reference numbers:
Section of the related art:

| | |
|---|---|
| 01 - heteromorphic edge | 02 - light bar |
| 03 - light guiding plate | 04 - shadow area |

Section according to some embodiments of the disclosure:

| | |
|---|---|
| 1 - light emitting diode | 11 - bracket |
| 111 - first side plate | 111a - first side plate #1 |
| 111b - first side plate #2 | 112 - second side plate |
| 113 - base plate | 12 - light emitting diode chip |
| 13 - bonding pad | 14 - metal wire |
| 15 - phosphor layer | 10 - backlight device |
| 1′- light emitting diode | 2′- light guiding plate |
| 2 - optical mebrane | 3 - light source |
| 4 - first light emitting diode | 5 - light-emitting region |
| 51 - first region | 52 - second region |
| 6 - non-light-emitting region | 7 - heteromorphic edge |
| 61 - first non-light-emitting region | 62 - second non-light-emitting region |
| 20 - lower polarizer | 30 - display panel |
| 31 - array substrate | 32 - color film substrate |
| 33 - liquid crystal layer | 40 - upper polarizer |
| 50 - cover plate | 100 - display device |
| 200 - mobile terminal | |

### DETAILED DESCRIPTION OF THE EMBODIMENTS

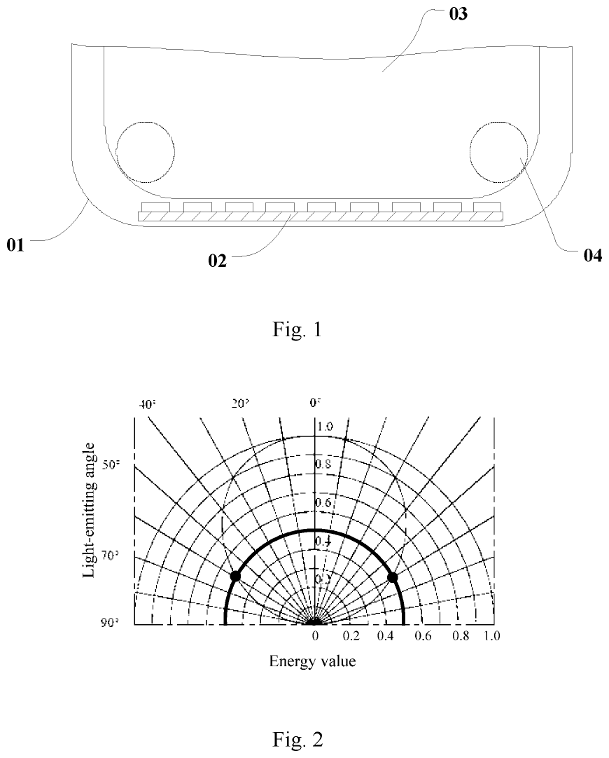

In order to increase a light-emitting angle of a light emitting diode, reduce a shadow of a backlight device and improve display effect of a display device, the embodiments of the disclosure provide a light emitting diode, a backlight device and a display device. FIG. 1 is a structural schematic diagram of the partial section of a backlight device according to some embodiments in the related art. In the related art, with the development of a narrow border of a mobile terminal, an edge of the backlight device begins to present a heteromorphic edge 01. More commonly, a corner of the backlight device is a rounded-corner edge. When a light bar 02 of the backlight device is arranged, it is difficult for the light bar 02 to extend to a position of the heteromorphic edge 01 of the display device due to the limit of the rounded-corner edge. Thus, it is difficult for the light bar 02 to completely cover a light incidence surface of a light guiding plate 03 in the extension direction, so that it is difficult for the light emitting diodes at two sides of the light bar 02 to be close to two side edges of the light guiding plate 03. Therefore, a relatively obvious shadow area 04 is formed in the rounded-corner region, which leads to a shadow problem of the backlight device and causes a poorer display effect of the display device.

Referring to FIG. 2, FIG. 2 is a schematic diagram of a brightness of a light emitting diode according to some embodiments in the related art. FIG. 2 illustrates a distribution situation of the light-emitting angles of the light emitting diode in the related art. Due to a light-proof design of a packaging side frame of the light emitting diode in the related art, an emergent light of the light emitting chip may only emit along an edge of a side frame of the light emitting diode, which severely affects a light-emitting angle of the light emitting diode. In one embodiment, an energy value of the light emitting diode is 0.5 which meets a light emission luminance requirement. The current light-emitting angle of one light emitting diode is 120° (60° at left and right respectively). For the rounded-corner edge of the backlight device of FIG. 1, the light emitting diode with the above light-emitting angle may not provide the sufficient light intensity at the edge, to thereby cause the shadow area.

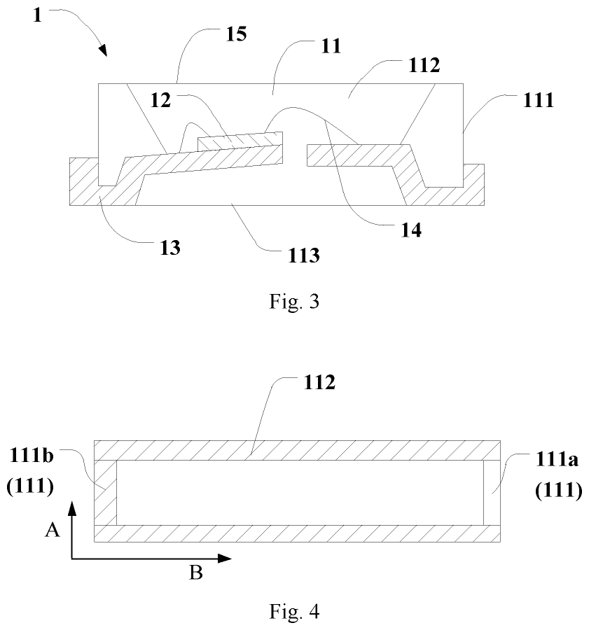

As shown in FIGS. 3 and 4, FIG. 3 is a schematic diagram of a cross-section structure of a light emitting diode according to some embodiments of the disclosure, and FIG. 4 is a top view of a light emitting diode of another embodiment of the disclosure. The light emitting diode 1 provided by the embodiments of the disclosure includes a bracket 11 and a light emitting diode chip 12. The bracket 11 includes two first side plates 111 arranged opposite to each other, two second side plates 112 arranged opposite to each other, and a base plate 113. The two first side plates 111 arranged opposite to each other, the two second side plates 112 arranged opposite to each other, and the base plate 113 may form a receptacle in which the light emitting diode chip 12 is arranged. At least one of the two first side plates 111 is a light-transmitting side plate.

Referring to FIGS. 3 and 4, the light emitting diode 1 includes the bracket 11, and the light emitting diode chip 12, a bonding pad 13, a metal wire 14 and a phosphor layer 15 which are arranged in the bracket 11. The first side plates 111, the second side plates 112 and the base plate 113 of the bracket 11 form a receptacle in which the light emitting diode chip 12 is arranged. The light emitting diode chip 12 is electrically connected to the bonding pad 13 via the metal wire 14. When the light emitting diode 1 is fixed to the circuit board, it may be attached on the circuit board by welding or by the Surface Mount Technology (SMT) to electrically connect the bonding pad 13 to the circuit board, so that the light emitting diode 1 is electrically connected and fixedly installed to the circuit board. The phosphor layer 15 is formed at one side of the notch of the receptacle, and the lights emitted by the chip motivate the phosphor layer 15 to emit the lights, implementing the light emitting of the light emitting diode 1.

In some embodiments, the light emitting diode as well as the components, structures and position relationship contained therein, as shown in FIGS. 3 and 4, are only exemplarily illustrative and an embodiment, but the structures and component layout may be designed as needed in the practical application. In one embodiment, as illustrated in FIG. 3, the light emitting diode chip 12 is obliquely arranged, but the feature does not limit the installing form of the light emitting diode chip. The structure of the bonding pad 13 is also only exemplarily illustrative, and so on.

In some embodiments of the disclosure, at least one of the first side plates 111 is a light-transmitting side plate, one of the first side plate 111 in the light emitting diode 1 shown in FIG. 4 is the light-transmitting side plate. In some embodiments, as shown in FIG. 4, the first side plates 111 include a first side plate #1 111a and a first side plate #2 111b, where the first side plate #1 111a is a light-transmitting side plate, and the first side plate #2 111b is a light-proof side plate. The lights may emit from the light-transmitting side plate, to thereby increase the light-emitting angle of the light emitting diode 1. When the light emitting diode 1 is installed on the backlight device, the shadow of the backlight device may be reduced and the display effect of the display device may be improved.

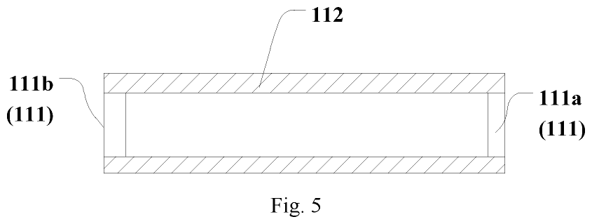

In some embodiments, referring to FIG. 5 which is a top view of a light emitting diode according to another embodiment of the disclosure, both of the two first side plates 111 in the light emitting diode 1 as shown are the light-transmitting side plates, that is, both of the first side plate #1 111a and the first side plate #2 111b are the light-transmitting side plates, so that the light-emitting angles at two sides of the light emitting diode 1 may be increased.

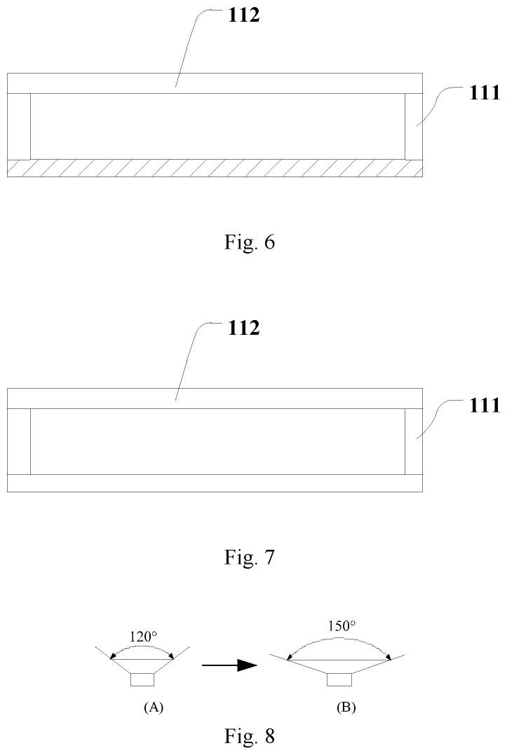

In some embodiments, at least one of the second side plates 112 is a light-transmitting side plate. Referring to FIG. 6 which is a top view of a light emitting diode according to another embodiment of the disclosure, one of the second side plates 112 in the light emitting diode 1 as shown is the light-transmitting side plate. In these embodiments, the second side plates 112 may also be the light-transmitting side plates besides the first side plates 111. When applied to the backlight device, the light emitting diode 1 in this embodiment may be applied to the straight-down backlight device, to thereby increase the light-emitting angle of the light emitting diode 1. In some embodiments, referring to FIG. 7 which is a top view of a light emitting diode of another embodiment of the disclosure, both of the two second side plates 112 in the light emitting diode 1 as shown are the light-transmitting side plates. In these embodiments, all the side plates of the bracket 11 of the light emitting diode 1 are the light-transmitting side plates, so that light-mixing effect is better.

In some embodiments, continue to refer to FIG. 5, where the second side plates 112 are the light-proof side plates. In these embodiments, the bracket 11 of the light emitting diode 1 has the better transmission of light in only one direction. When applied to the backlight device, the light emitting diode 1 in this embodiment may be applied to the side-entry backlight device. Thus, when the light emitting diode 1 is installed, the second side plates 112 are parallel to the light-emitting surface of the backlight device, that is, the first side plates 111 are towards the two ends of the light bar, so that the backlight device not only may increase the light-emitting effect and uniformity of the backlight device, but also is not easy to produce the light leakage.

Referring to FIG. 8 which is a contrast diagram of the light-emitting angles of the light emitting diode before and after the improvement, showing a contrast diagram of the light-emitting angles of one light emitting diode 1 before and after the improvement, the bracket 11 of the light emitting diode 1 is improved in the technical solution of the present application. FIG. 8(A) shows the light-emitting angle of the light emitting diode is 120° in the prior art, and FIG. 8(B) shows the light-emitting angle of the light emitting diode 1 is 150° in an embodiment of the present application. The above is only one embodiment. In the practical application, the light-emitting angle of the light emitting diode 1 may reach about 140° to 150° in the technical solution of the present application, and of course, may also reach the higher value in other embodiments. As can be seen, the light-emitting angle of the light emitting diode 1 is increased. After the light emitting diode 1 is applied to the backlight device 1, the shadow problem of the rounded-corner edge may be relieved.

In some embodiments, the bracket 11 of the light emitting diode 1 is an integrally-formed bracket, that is, the first side plates 111, the second side plates 112 and the base plate 113 are the integrally-formed structure. In one embodiment, the bracket 11 of the light emitting diode 1 may be fabricated by the double injection process, to increase the integrality and strength of the bracket 11 of the light emitting diode 11 and also implement the combination of the side plates of two materials.

Continue referring to FIGS. 4-7, and in some embodiments, the length of the second side plate 112 in the second direction is larger than the length of the first side plate 111 in the first direction, where the first direction intersects with the second direction.

In some embodiments, the first side plate 111 extends in the first direction, and the second side plate 112 extends in the second direction, so that the size of the first side plate 111 of the bracket 11 of the light emitting diode 1 is smaller than the size of the second side plate 112.

In some embodiments, the shape of the cross section of the bracket 11 of the light emitting diode 1 is not limited and may be designed as needed. Continue referring to FIG. 4, and in one embodiment, the cross section of the bracket 11 of the light emitting diode 1 is rectangle, that is, the first side plates 111 are perpendicular to the second side plates 112. In some embodiments, the first direction A is perpendicular to the second direction B, that is, the second side plates 112 are located at the long sides of the bracket 11 and the first side plates 111 are located at the short sides of the bracket 11.

In some embodiments, when the first side plate 111 is the light-transmitting side plate, the material of the light-transmitting side plate includes one or more of silicone, epoxy resin, tempered glass, acrylic, polycarbonate, polypropylene or polyvinylidene fluoride. The suitable material for fabricating the first side plate 111 which transmits the lights may be selected according to the actual demand. Further, when the second side plate 112 is also the light-transmitting side plate, the material of this light-transmitting side plate includes one or more of silicone, epoxy resin, tempered glass, acrylic, polycarbonate, polypropylene or polyvinylidene fluoride.

In some embodiments, the light-transmitting side plate may be fabricated as the transparent side plate by adjusting the compositions and the fabricating process, that is, the light transmitting effect is better, so that the transparent effect may be achieved and the more lights may be transmitted, facilitating the increase of the light emission luminance of the light emitting diode.

For the selection of the material of the light-proof side plate, the material includes one or more of the poly-para-phenylene terephthalamide, poly-terephthalic acid-cyclohexylene-dimethylene ester resin, epoxy resin side plate and unsaturated polyester-glass fiber reinforced sheet molding compound. The selection may be made according to the actual demand.

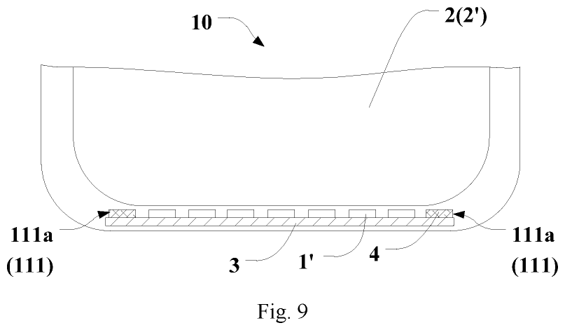

Referring to FIG. 9 which is a schematic diagram of the partial structure of a display device according to some embodiments of the disclosure, an embodiment of the present application further provides a backlight device 10. The backlight device 10 includes at least one optical membrane 2 and a light source 3 which includes a plurality of light emitting diodes 1′. At least one light emitting diode 1′ is a first light emitting diode 4 which is the light emitting diode 1′ in any one of the technologies described above.

The light source 3 of the backlight device 10 may be a light bar. The light bar includes a plurality of light emitting diodes 1′. At least one of the above-mentioned light emitting diodes 1′ is the first light emitting diode 4 of which the light-emitting angle is larger, so the probability that the backlight device 10 produces the shadow is reduced, to thereby increase the work efficiency of the backlight device 10 and improve the display effect of the display device using the backlight device 10.

Continue referring to FIG. 9. the plurality of light emitting diodes 1′ of the light source 3 are arranged along at least one side of the periphery of the optical membrane 2, where the optical membrane 2 includes a light guiding plate 2′. The light-emitting surface of the light source 3 intersects with the light-emitting surface of the light guiding plate 2′, the light emitting diodes at least at the beginning and end of the light source 3 are the first light emitting diodes 4, and the side plates of the first light emitting diodes 4 towards the beginning or end of the light source 3 are the first side plates 111.

In some embodiments, the backlight device 10 is the side-entry backlight device 10. The light source 3 provided with a plurality of light emitting diode is arranged at one side of the light guiding plate 2′. The light-emitting surface of the light source 3 intersects with the light-emitting surface of the light guiding plate 2′. Further, the light-emitting surface of the light source 3 may be perpendicular to the light-emitting surface of the light guiding plate 2′. In some embodiments, the light emitting diodes of the light source 3 are arranged successively to form the light bar. The light emitting diodes at the beginning and end of the light source 3 are the first light emitting diodes 4, and the side plates of the first light emitting diodes 4 towards the beginning or end of the light source 3 are the light-transmitting side plates. Thus, in view of the whole light source 3, the side plates at the two ends of the light source 3 are the light-transmitting side plates, that is, the first side plates #1 111a are located at the two sides of the light source, so that the lights of the light emitting diodes at the two sides of the light source 3 may be incident to the edge of the light guiding plate, to improve the shadow problem produced by the backlight device 10.

In some embodiments, the second side plates 112 of all the first light emitting diodes 4 in the above side-entry backlight device 10 towards the light-emitting surface of the backlight device 10 are the light-proof side plates. In these embodiments, the second side plates 112 which do not transmit the lights may play a shading role, to thereby reduce the light leakage produced by the backlight device 10. The work efficiency of the backlight device 10 is increased.

Referring to FIG. 12, FIG. 12 is a contrast diagram of the states of installing the light emitting diode to the light bar before and after the improvement, showing the contrast diagram of the states of installing the light emitting diode 1 to the light bar before and after the improvement. In some embodiments, after the plurality of light emitting diodes 1 described above are installed to the light bar, the light-mixing distance L of the light emitting diodes 1 may further be reduced under the same density of the light emitting diodes 1, so that the distance between the light guiding plate and the light emitting diode 1 may be reduced, to facilitate the further decrease of the border of the backlight device. Furthermore, in case of maintaining the same light-mixing distance L, the distance between the two adjacent light emitting diodes 1 may be increased, to thereby decrease the number of the light emitting diodes 1 used by the backlight device and facilitate the reduced cost.

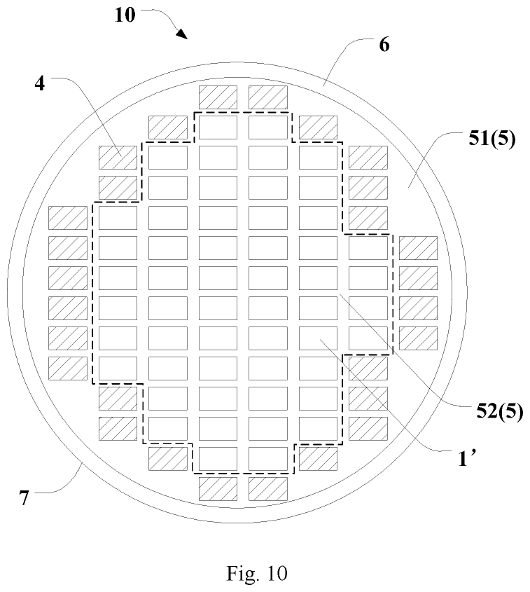

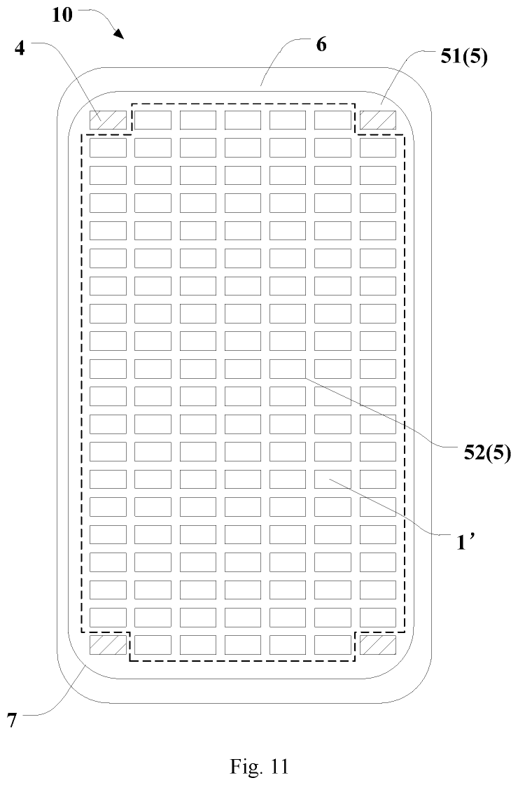

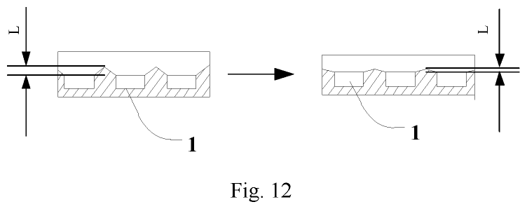

Referring to FIGS. 10 and 11, FIG. 10 is a structural schematic diagram of a display device according to another embodiment of the disclosure, and FIG. 11 is a structural schematic diagram of a display device according to another embodiment of the disclosure. In some embodiments, a plurality of light emitting diodes 1′ of the light source 3 are arranged in an array, and the light-emitting surface of the light source 3 is parallel to the light-emitting surface of the backlight device 10.

In some embodiments, the backlight device 10 is a straight-down backlight device 10 of which the light-emitting efficiency is higher, to thereby increase work efficiency of the backlight device 10 and reduce cost of the light emitting diodes 1′.

Continue referring to FIGS. 10 and 11, and in some embodiments, the backlight device 10 includes a light-emitting region 5 and a non-light-emitting region 6, where the light-emitting region 5 includes a first region 51 (the region between the dotted line and the solid line in the figures) and a second region 52 (the closed region outlined by the dotted line in the figures), the non-light-emitting region 6 surrounds the first region 51, the first region 51 surrounds the second region 52, each of the first region 51 and the second region 52 includes the plurality of light emitting diodes 1′, and the first region 51 includes at least one of the first light emitting diodes 4.

It shall be noted that, “surrounding” described above includes the full surrounding or half surrounding case. In one embodiment, FIG. 11 illustrates a top view of the backlight device 10 in some embodiments, in which the light-emitting region of the backlight device 10 is a circular region, so all the edges of the light-emitting region are heteromorphic edges 7 (all the edges of the backlight device as shown in FIG. 11 are the heteromorphic edges, and specifically, the heteromorphic edges are the arc edges). In these embodiments, the first region 51 fully surrounds the second region 52, that is, the first region 51 encompasses the second region 52. In these embodiments, the first region 51 includes the first light emitting diodes 4, so that the heteromorphic edges 7 of the backlight device 10 may have the sufficient brightness, to increase the work efficiency of the backlight device 10. The light-emitting region 5 of the backlight device 10 may also have the rhombic, wavy-shaped or irregular-shaped edge, or the light-emitting region 5 of the backlight device 10 may have the rectangular edge, and it is also possible to make the first region 51 encompass the second region 52, to thereby increase the luminous intensity of the whole edge of the light-emitting region of the backlight device 10.

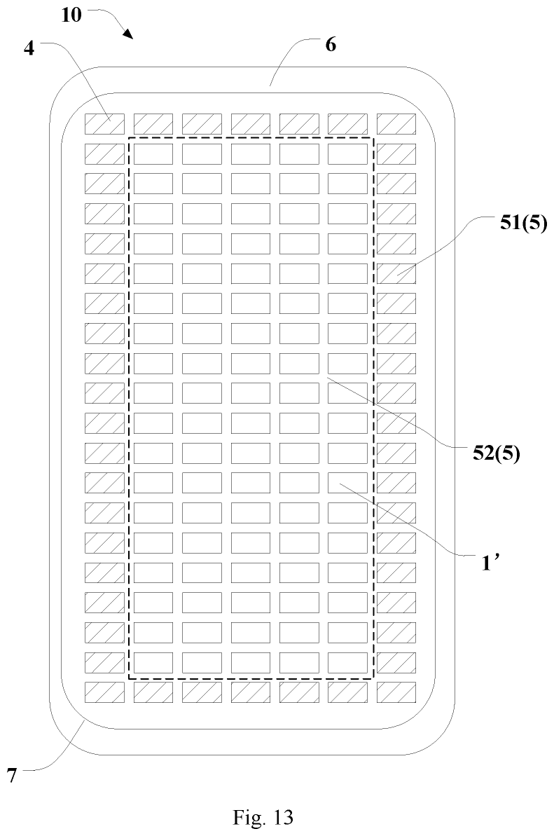

FIG. 11 illustrates a top view of the backlight device 10 in some embodiments. In these embodiments, the light-emitting region of the backlight device 10 has the rounded-corner edges, so the region near the rounded-corner edges may be taken as the first region 51 (the region between the dotted line and the solid line in the figure). In these embodiments, the first region 51 encompasses by half the second region 52 (the closed region outlined by the dotted line in the figure), so there are the first light emitting diodes 4 at the rounded-corner edges of the backlight device 10, to thereby increase the brightness of the heteromorphic edges 7 of the backlight device 10 and increase the work efficiency of the backlight device 10. As shown in FIG. 13 which is a structural schematic diagram of a display device of another embodiment of the disclosure and a top view of the backlight device 10 in another embodiment, in this embodiment, all the edges of the backlight device 10 use the first light emitting diodes 4, to thereby increase the brightness of the heteromorphic edges 7 of the backlight device 10 and increase the work efficiency of the backlight device 10.

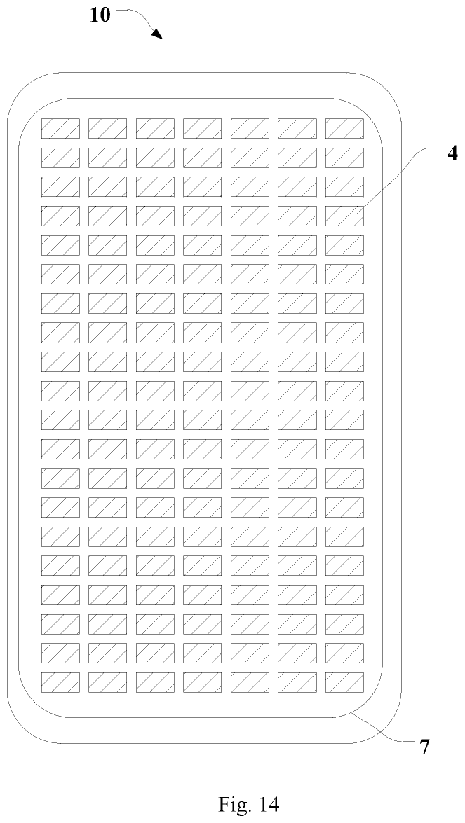

In some embodiments, referring to FIG. 14 which is a structural schematic diagram of a display device of another embodiment of the disclosure, all the plurality of light emitting diodes of the light source 3 described above may be the first light emitting diodes 4. In this embodiment, not only the lights may be incident to the edges of the light guiding plate to reduce the shadow of the heteromorphic edges 7, but also the light-mixing distance of the light emitting diodes may be decreased to thereby reduce the distance between the light guiding plate and the light emitting diodes. For the side-entry backlight device 10, it is beneficial to further reduce the border of the backlight device 10, to thereby reduce the border of the display device; and for the straight-down backlight device 10, it is beneficial to further thin the backlight device 10, to thereby thin the display device. Furthermore, in case of maintaining the same light-mixing distance, the distance between the two adjacent light emitting diodes may be increased, to thereby decrease the number of the light emitting diodes used by the backlight device 10 and facilitate the reduced cost of the backlight device 10. In one embodiment, all the first and second side plates of the first light emitting diodes 4 in this embodiment may be the light-transmitting side plates, so that it is more beneficial to decrease the light-mixing distance of the light emitting diodes, to thereby further thin the display device.

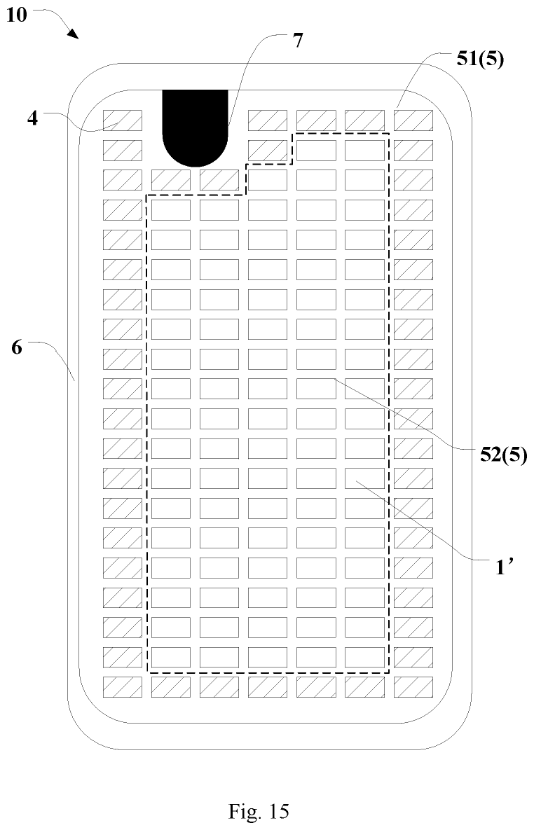

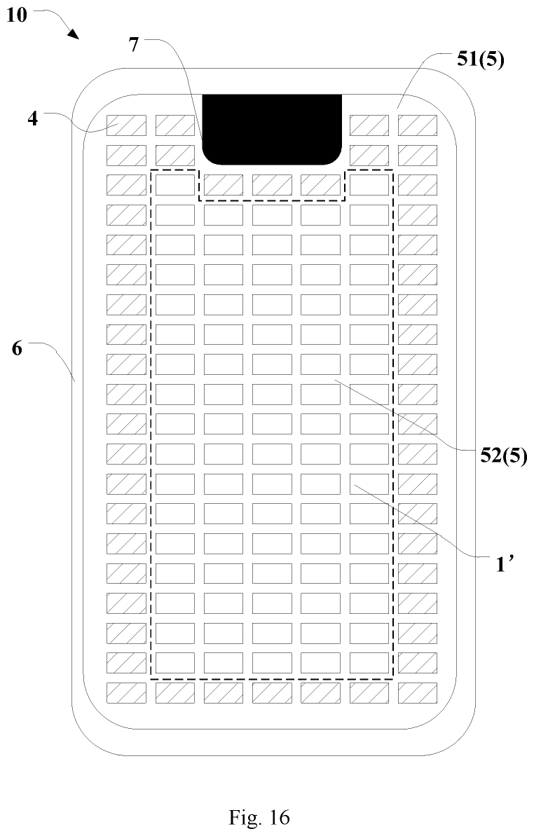

Referring to FIGS. 10 and 11, the backlight device 10 provided by the present application includes a light-emitting region 5 and a non-light-emitting region 6, where the light-emitting region 5 includes at least one heteromorphic edge 7, and the non-light-emitting region 6 surrounds the light-emitting region 5. Similarly, in this embodiment, the involved “surrounding” also includes the two cases of full surrounding and half surrounding. The backlight device 10 with the heteromorphic edge mentioned in this embodiment has the rounded corners as shown in FIG. 11, and in addition to this, in the structural schematic diagram of the display device of another embodiment of the disclosure as shown in FIG. 15, the backlight device also has the notch structure, or in the structural schematic diagram of the display device of another embodiment of the disclosure as shown in FIG. 16, the backlight device also has the “bang” structure, where this backlight device 10 has the heteromorphic edge 7 at which the first light emitting diodes 4 provided by the present application are used, to increase the light emitting uniformity and brightness of the backlight device 10.

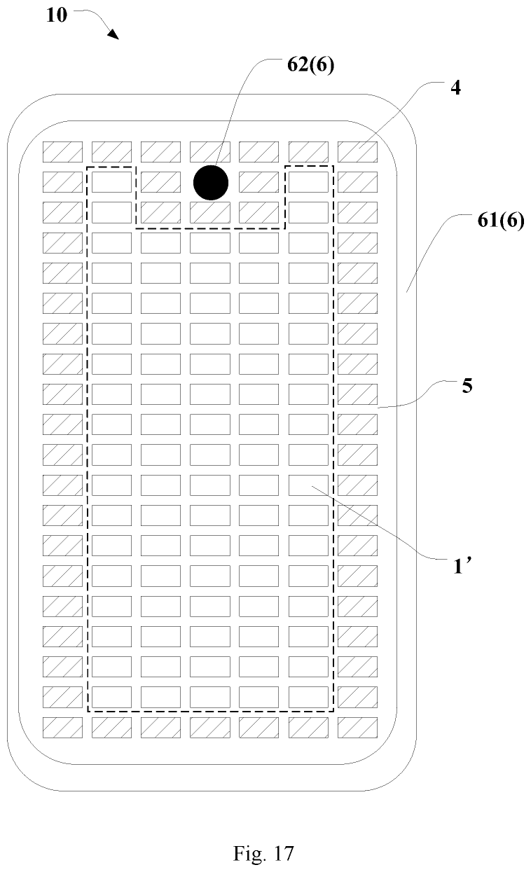

In some embodiments, referring to FIG. 17 which is a structural schematic diagram of a display device of another embodiment of the disclosure, the backlight device 10 includes a light-emitting region 5, a first non-light-emitting region 61 and a second non-light-emitting region 62, where the first non-light-emitting region 61 surrounds the light-emitting region 5, and the light-emitting region 5 surrounds the second non-light-emitting region 62. In this embodiment, the first non-light-emitting region 61 is the edge of the backlight device 10, and the second non-light-emitting region 62 may be the circular hole surrounded by the light-emitting region 5 of the backlight device 10. The shape of the second non-light-emitting region may be circle, oval or polygon, which is not limited specifically by the disclosure. The light emitting diodes of the backlight device 10 close to the second non-light-emitting region 62 may be the first light emitting diodes 4, so that the lights around the second non-light-emitting region is relatively uniform.

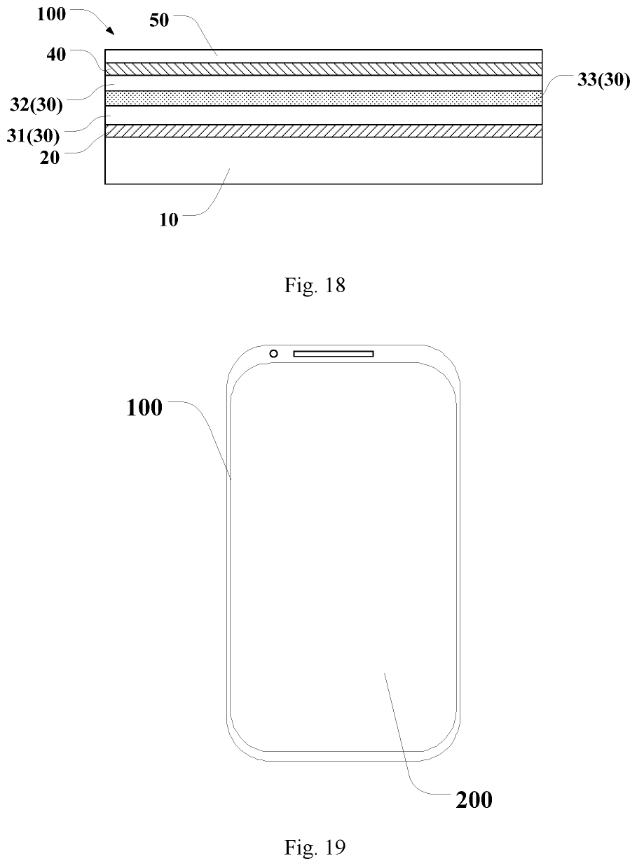

As shown in FIG. 18 which is a structural schematic diagram of a display device of another embodiment of the disclosure, the present application further provides a display device 100 which contains the backlight device 10 in any one of the embodiments of the present application. The display device 100 includes the backlight device 10, a lower polarizer 20, a display panel 30, a upper polarizer 40 and a cover plate 50 superposed in sequence, and the display panel 30 further includes an array substrate 31 and a color film substrate 32 in paired box with the array substrate 31, and there is a liquid crystal layer 33 between the array substrate 31 and the color film substrate 32. The light-emitting uniformity of the backlight device 10 is better, the probability of producing the shadow is lower, and the display effect of the display device 100 is better.

As shown in FIG. 19 which is structural schematic diagram of a mobile terminal of another embodiment of the disclosure, it is a mobile terminal 200 including the display device 100 described above. The backlight device 10 of the mobile terminal 200 uses the first light emitting diode having the light-transmitting side plate, so the light-emitting uniformity is better, the probability of producing the shadow is lower, the display effect of the display device 100 is better, and thus the using effect of the mobile terminal is also better.

In some embodiments, the specific type of the mobile terminal is not limited, and the mobile terminal may be, in one embodiment, a smart watch, a mobile phone, a tablet computer, a laptop, an E-ink book, a television, or any other electronic equipment with the display function. In one embodiment, the mobile terminal as shown in FIG. 11 is a mobile phone.

What is claimed is:

1. A light emitting diode, comprising:
a bracket, comprising two first side plates arranged opposite to each other, two second side plates arranged opposite to each other, and a base plate, wherein at least one of the two first side plates is a light-transmitting side plate; and
a light emitting diode chip, arranged in a receptacle, wherein the receptacle is formed by the two first side plates arranged opposite to each other, the two second side plates arranged opposite to each other, and the base plate.

2. The light emitting diode according to claim 1, wherein at least one of the two second side plates is a light-transmitting side plate.

3. The light emitting diode according to claim 1, wherein the two second side plates are non-transparent side plates.

4. The light emitting diode according to claim 1, wherein the bracket is a formed integral bracket.

5. The light emitting diode according to claim 1, wherein a length of the second side plate in a second direction is greater than a length of the first side plate in a first direction, wherein the first direction intersects with the second direction.

6. The light emitting diode according to claim 1, wherein a material of the light-transmitting side plate comprises one or more of silicone, epoxy resin, tempered glass, acrylic, polycarbonate, polypropylene or polyvinylidene fluoride.

7. A backlight device, comprising:
at least one optical membrane and a light source comprising a plurality of light emitting diodes, wherein at least one of the plurality of light emitting diodes is a first light emitting diode, and the first light emitting diode is a light emitting diode comprising:
a bracket, comprising two first side plates arranged opposite to each other, two second side plates arranged opposite to each other, and a base plate, wherein at least one of the two first side plates is a light-transmitting side plate; and
a light emitting diode chip, arranged in a receptacle, wherein the receptacle is formed by the two first side plates arranged opposite to each other, the two second side plates arranged opposite to each other, and the base plate.

8. The backlight device according to claim 7, wherein at least one of the two second side plates is a light-transmitting side plate.

9. The backlight device according to claim 7, wherein the two second side plates are non-transparent side plates.

10. The backlight device according to claim 7, wherein the bracket is a formed integral bracket.

11. The backlight device according to claim 7, wherein a length of the second side plate in a second direction is greater than a length of the first side plate in a first direction, wherein the first direction intersects with the second direction.

12. The backlight device according to claim 7, wherein a material of the light-transmitting side plate comprises one or more of silicone, epoxy resin, tempered glass, acrylic, polycarbonate, polypropylene or polyvinylidene fluoride.

13. The backlight device according to claim 7, wherein the plurality of light emitting diodes of the light source are arranged along at least one side of the periphery of the optical membrane, the optical membrane comprises a light guiding plate, a light-emitting surface of the light source intersects with a light-emitting surface of the light guiding plate, the light emitting diodes at least at the beginning and end of the light source are first light emitting diodes, and side plates of the first light emitting diodes towards the beginning or end of the light source are first side plates, and the first side plates are light-transmitting side plates.

14. The backlight device according to claim 7, wherein the plurality of light emitting diodes of the light source are arranged in an array, and a light-emitting surface of the light source is parallel to a light-emitting surface of the backlight device.

15. The backlight device according to claim 14, wherein the backlight device comprises a light-emitting region and a non-light-emitting region, wherein the light-emitting region comprises a first region and a second region, the non-light-emitting region surrounds the first region, the first region surrounds the second region, each of the first region and the second region comprises the plurality of light emitting diodes, and the first region comprises at least one first light emitting diode.

16. The backlight device according to claim 13, wherein the plurality of light emitting diodes, of the light source, are first light emitting diodes.

17. The backlight device according to claim 14, wherein the plurality of light emitting diodes, of the light source, are first light emitting diodes.

18. The backlight device according to claim 7, wherein the backlight device comprises a light-emitting region and a non-light-emitting region, wherein the light-emitting region comprises at least one heteromorphic edge, and the non-light-emitting region surrounds the light-emitting region.

19. The backlight device according to claim 7, wherein the backlight device comprises a light-emitting region, a first non-light-emitting region and a second non-light-emitting region, wherein the first non-light-emitting region surrounds the light-emitting region, and the light-emitting region surrounds the second non-light-emitting region.

20. A display device, comprising:
a backlight device comprising at least one optical membrane and a light source comprising a plurality of light emitting diodes, wherein at least one of the plurality of light emitting diodes is a first light emitting diode, and the first light emitting diode is a light emitting diode comprising:
a bracket, comprising two first side plates arranged opposite to each other, two second side plates arranged opposite to each other, and a base plate, wherein at least one of the two first side plates is a light-transmitting side plate; and
a light emitting diode chip, arranged in a receptacle, wherein the receptacle is formed by the two first side plates arranged opposite to each other, the two second side plates arranged opposite to each other, and the base plate.
